(19) United States
(12) Patent Application Publication
(10) Pub. No.: US 2008/0236489 A1
(43) Pub. Date: Oct. 2, 2008

(54) Plasma Processing Apparatus

(75) Inventor: Koji Kotani, Hyogo-Ken (JP)

Correspondence Address: SMITH, GAMBRELL & RUSSELL, 1130 CONNECTICUT AVENUE, N.W., SUITE 1130, WASHINGTON, DC, 20036, US

(73) Assignee: TOKYO ELECTRON LIMITED, MINATO-KU TOKYO (JP)

(21) Appl. No.: 10/586,660

(22) PCT Filed: Jan. 19, 2005
(86) PCT No.: PCT/JP05/00601

§ 371 Date: Jul. 19, 2006

(30) Foreign Application Priority Data
Jan. 19, 2004 (JP) 2004-010978

(51) Int. Cl. C23C 16/44

(52) U.S. Cl. 118/723 AN

(57) ABSTRACT

The plasma processing apparatus includes: a processing container 11 having a holding stage 13 that holds a substrate 12 to be processed; a micro-wave transmission window 17 provided on or above the processing container, opposite to the substrate to be processed placed on the holding stage; a micro-wave antenna 20 provided above the processing container correspondingly to the micro-wave transmission window for supplying a micro-wave into the processing container; and a micro-wave electric power supplying source 32 connected to the micro-wave antenna. The plasma processing apparatus further includes an electric-field measuring unit 25, 26 that measures electric field strength of the micro-wave supplied by the micro-wave antenna, and a controlling unit 32a, 50A that controls the micro-wave electric power supplying source based on the electric field strength measured by the electric-field measuring unit. This enables a stable substrate process.

### FIELD OF THE INVENTION

This invention relates to a plasma processing apparatus, in particular to a micro-wave plasma processing apparatus.

### BACKGROUND ART

A plasma processing step and a plasma processing apparatus are necessary in manufacturing recent hyperfine semiconductor devices having a gate length of about 0.1 μm or shorter, which are called deep submicron devices or deep sub-quarter-micron devices, or in manufacturing high resolution flat displaying devices including liquid crystal displaying devices.

As a plasma processing apparatus used in manufacturing the semiconductor devices or the liquid crystal displaying devices, a micro-wave plasma processing apparatus has been proposed, which uses a high density plasma excited by a micro-wave electric field without using any direct-current magnetic field. For example, a plasma processing apparatus has been proposed wherein a micro-wave is radiated into a processing container from a plane antenna (radial line slot antenna) having a large number of slots arranged so as to uniformly generate the micro-wave and wherein an electric field of the micro-wave ionizes a gas in the processing container so as to excite a plasma.

The micro-wave plasma excited by the above method can achieve a high plasma density over a large area just under the antenna, which makes it possible to conduct a uniform plasma process within a shorter time. In addition, in the micro-wave plasma formed by the above method, since the plasma is excited by the micro-wave, electron temperature is lower, so that it is possible to avoid damages of substrates to be processed and/or metal contamination. Furthermore, the uniform plasma can be easily excited above a larger substrate, so that the micro-wave plasma is easily applicable in manufacturing semiconductor devices using a larger semiconductor substrate and in manufacturing larger crystal liquid displaying devices.

FIG. 7 shows a structure of a plasma processing apparatus 500, which is a conventional substrate processing apparatus.

The plasma processing apparatus 500 has a substrate processing part 100. The substrate processing part 100 has a space 101a therein, and has a holding stage 103 for holding a substrate to be processed 102 by means of an electrostatic chuck.

A radial slot antenna 200 is provided on the substrate processing part 100. The radial slot antenna 200 is provided with a micro-wave supplying part 300 that supplies a micro-wave to the radial slot antenna 200.

The micro-wave supplying part 300 has: waveguides 301 connected to coaxial waveguides 204 at a connecting part 200A; an oscillating part (magnetron) 303 connected to the coaxial waveguides 301 via an isolator 304; and an electric power supplying source 302 that supplies electric power to the oscillating part 303 via a wire part 307.

When the micro-wave is supplied to the radial line slot antenna 200, the electric power is supplied from the electric power supplying source 302 to the oscillating part 303, the micro-wave is formed in the oscillating part 303, and the micro-wave is introduced from the coaxial waveguides 301 to the radial line slot antenna 200 via the isolator 304. The isolator 304 has a function to protect the oscillating part and the electric power supplying source from reflection wave of the micro-wave.

The waveguide 301 is provided with: a detecting means 308A consisting of a directional coupler that detects traveling wave of the micro-wave, that is, traveling electric power; and a detecting means 308B consisting of a directional coupler that detects reflected wave of the micro-wave, that is, reflected electric power. The detected traveling electric power and the detected reflected electric power are fed back to the electric power supplying source 302 via a wiring part 808a and a wiring part 808b

The electric power supplying source 302 controls an introduction electric power to the oscillating part 303 in such a manner that the traveling wave electric power coincides with an electric power set in the electric power supplying source 302. In addition, in order to protect the oscillating part and the electric power supplying source, a mechanism is provided which stops the supply of the electric power when the reflected electric power becomes higher than a predetermined value.

In addition, the waveguide 301 is provided with a matching part 305 that adjusts impedance so as to minimize reflection of the micro-wave. The matching part 305 has a mechanism which adjusts the impedance by controlling a variable short-circuit unit based on a detected value of a detecting part 306 that detects a standing wave of the micro-wave in the waveguide 301, so as to minimize reflection of the micro-wave.

In addition, control of the electric power supplying source 302 such as setting of the electric power of the electric power supplying source 302, control and monitoring of the oscillating part 303, the isolator 304 and the matching part 305, control of an introduction way (not shown) for introducing a plasma gas into the processing container 100, control of the processing container 100 such as gas-discharging of the processing container, and so on are carried out by a controlling unit 500A.

These techniques are disclosed in JP Laid-Open Publication No. 2002-299331.

However, in the plasma processing apparatus 500, the micro-wave detected by the detecting means 308A and 308B, and the micro-wave detected by the detecting means 306 are the (state of the) micro-wave in the waveguide 301, which may not coincide with the (state of the) micro-wave introduced from the radial line slot antenna 200 and having a direct effect on the process to the substrate.

For example, in the processing apparatus 500, if the installation location of the electric power supplying source 302 and/or the oscillating part 303 is changed, the shape and/or the length of the waveguide 301 may have to be changed. Thus, after the waveguide 301 is modified, even if the micro-wave is introduced to the radial line slot antenna 200 based on the state of the micro-wave detected by the detecting means 308A and 308B, and/or the micro-wave detected by the detecting means 306, in order to conduct a process to the substrate, the result of the process may not be the same as that before the waveguide 301 is modified.

The reason is thought because the state of the micro-wave actually supplied to the radial line slot antenna 200 is changed by modifying the waveguide 301. This problem arises when the state of the micro-wave in the waveguide 301 is used to control the supplying state of the micro-wave.

In addition, for example, if the plasma processing apparatus 500 is mass-produced, when the installation location of the electric power supplying source and/or the oscillating part is changed for each apparatus as required, the difference between the apparatuses in the micro-wave supplying part 300 including the waveguide 301 becomes the difference between the apparatuses in the state of the micro-wave introduced into the radial line slot antenna 200. Then, the results of the substrate process may not be even between the apparatuses, and/or the substrate process may be unstable because it becomes difficult to introduce the micro-wave normally.

Thus, the object of this invention is to provide a new and useful plasma processing apparatus which can solve the above problems.

Specifically, the object of this invention is to provide a plasma processing apparatus which achieves a stable substrate process by stabilizing a state of a micro-wave used for the substrate process.

### SUMMARY OF THE INVENTION

In order to achieve the above object, the invention is a plasma processing apparatus comprising: a processing container having a holding stage that holds a substrate to be processed; a micro-wave transmission window provided on or above the processing container, opposite to the substrate to be processed placed on the holding stage; a micro-wave antenna provided on or above the micro-wave transmission window, opposite to the micro-wave transmission window, for supplying a micro-wave into the processing container; a micro-wave electric power supplying source connected to the micro-wave antenna; an electric-field measuring unit that measures electric field strength of the micro-wave supplied by the micro-wave antenna; and a controlling unit that controls the micro-wave electric power supplying source based on the electric field strength measured by the electric-field measuring unit.

The present invention may have a feature wherein the micro-wave antenna is fed via coaxial waveguides, and wherein the micro-wave antenna has: an antenna main body having an opening; a micro-wave radiation surface provided on or above the antenna main body so as to cover the opening, the micro-wave radiation surface having a plurality of slots; and a dielectric plate provided between the antenna main body and the micro-wave radiation surface.

The present invention may have a feature wherein the micro-wave antenna is a radial line slot antenna.

The present invention may have a feature wherein the electric-field measuring unit includes an electric-field measuring probe.

The present invention may have a feature wherein the electric-field measuring unit measures an electric voltage on or above a surface of the micro-wave transmission window.

The present invention may have a feature wherein the electric-field measuring unit is attached on or above the micro-wave antenna.

The present invention may have a feature wherein a plurality of electric-field measuring units is provided.

### BRIEF DESCRIPTION OF THE DRAWINGS

FIG. 1 is a schematic view showing a plasma processing apparatus according to an embodiment of the present invention;

FIG. 2 is a plan view showing a slot plate used for the plasma processing apparatus of FIG. 1;

FIG. 3A is a schematic sectional view showing an electric field measuring unit used for the plasma processing apparatus of FIG. 1;

FIG. 3B is an enlarged view of a diode used for the electric field measuring unit of FIG. 3A;

FIG. 4 is a perspective view showing an installation location of the electric field measuring unit of FIG. 3A;

FIG. 5A is a schematic view showing a standing wave formed by a micro-wave;

FIGS. 5B to 5D are schematic views showing installation locations of the electric field measuring unit of FIG. 3A;

FIG. 6 is a schematic view showing another embodiment of a plasma processing apparatus according to the present invention; and

FIG. 7 is a schematic view showing a relevant art of a plasma processing apparatus.

### DESCRIPTION OF THE PREFERRED EMBODIMENT

Hereinafter, embodiments of the present invention are explained in detail with reference to the attached drawings.

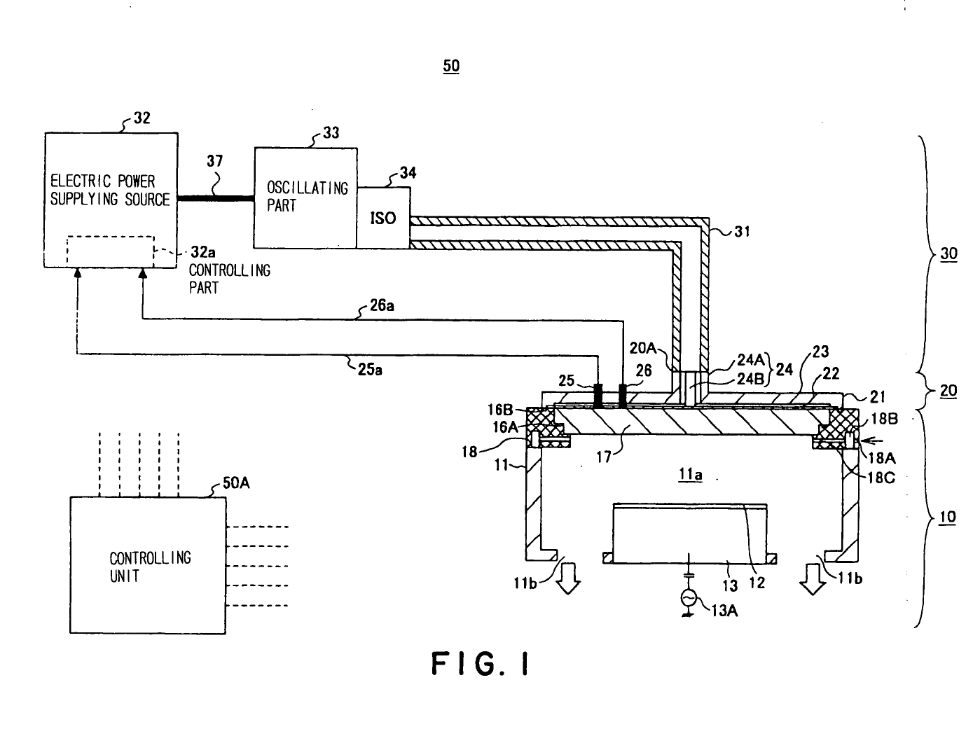

FIG. 1 shows the structure of a plasma processing apparatus 50 according to an embodiment of the present invention. With reference to FIG. 1, the plasma processing apparatus 50 has: a processing container 11 forming a space 11a therein; and a substrate processing part 10 provided in the processing container 11 with a holding stage 13 that holds a substrate to be processed 12 by means of an electrostatic chuck.

The space 11a in the processing container 11 is evacuated by a gas-discharging unit such as a vacuum pump, via at least two, preferably three or more, gas-discharging ports 11b formed around the holding stage 13 at regular intervals, that is, in an axial symmetric relationship to the substrate to be processed 12 placed on the holding stage 13.

A micro-wave transmission window 17 is provided as an outside (upper) wall of the processing container 11, opposite to the substrate to be processed 12. A plasma-gas introducing ring 18 for introducing a plasma gas into the processing container 11 is inserted between the micro-wave transmission window 17 and the processing container 11. The micro-wave transmission window 17 and the plasma-gas introducing ring 18 form the outside wall of the processing container 11, respectively.

The micro-wave transmission window 17 has a stepwise shape at a peripheral part thereof. The stepwise shape is adapted to be engaged with another stepwise shape of the plasma-gas introducing ring 18. In addition, airtightness in the processing space 11 is maintained by a sealing ring 16A.

The plasma gas is introduced from a plasma-gas introducing port 18A to the plasma-gas introducing ring 18, and then is diffused in a gas groove 18B formed in a substantially circular shape. The plasma gas in the gas groove 18B is supplied into the space 11a through a plurality of plasma-gas holes 18C communicated with the gas groove 18B.

A radial line slot antenna 20 is provided on the micro-wave transmission window 17. The radial line slot antenna 20 has: a disk-like slot plate 22 having a large number of slots, the slot plate 22 being in close contact with the micro-wave transmission window 17; a disk-like antenna main body 21 holding the slot plate 22 in an opening formed therein; and a slow-wave plate 23 consisting of a low-loss dielectric material such as Al₂O₃, SiO₂ or Si₃N₄, sandwiched between the slot plate 22 and the antenna main body 21. In addition, at an engaging part of the radial line slot antenna 20 and the micro-wave transmission window 17, a shielding ring 16B maintains gastight of the micro-wave.

The radial line slot antenna 20 is mounted on the processing container 11 via the plasma-gas introducing ring 18. A micro-wave is supplied to the radial line slot antenna 20 from a micro-wave supplying part 30 via coaxial waveguides 24. Among the coaxial waveguides 24, an outside waveguide 24A is connected to the disk-like antenna main body 21, and a central conductor 24B is connected to the slot plate 22 via an opening formed in the slow-wave plate 23. Then, the micro-wave supplied to the coaxial waveguides 24 is radiated from the slots, while traveling in radial directions between the antenna main body 21 and the slot plate 22.

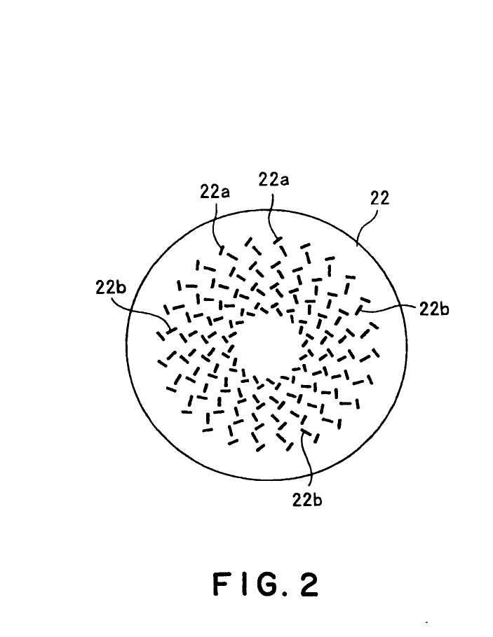

FIG. 2 shows the slots 22a, 22b formed in the slot plate 22.

With reference to FIG. 2, the slots 22a are arranged in concentric circles. The slots 22b are also formed in concentric circles, each slot 22b being arranged perpendicular to each corresponding slot 22a. The gap between the slots 22a or 22b in a radial direction of the slot plate 22 corresponds to a wavelength of the micro-wave compressed by the slow-wave plate 23. Thus, the micro-wave is radiated from the slot plate 22 as a substantially plane wave. At that time, since the pair of slots 22a, 22b has a perpendicular relationship, the radiated micro-wave forms circularly polarized wave including two perpendicular polarized components, which is introduced into the processing container 11 via the micro-wave transmission window 17.

Then, in the space 11a just under the micro-wave transmission window 17, a plasma is excited in the plasma gas supplied from the plasma-gas supplying ring 18.

According to the plasma processing apparatus 50, for example, a plasma oxidizing process, a plasma nitriding process, a plasma oxynitriding process, a plasma CVD process or the like may be conducted. In addition, a radio-frequency electric voltage may be applied from the radio-frequency electric power supplying source 13A to the holding stage 13, so that a reactive ion etching may be conducted to the substrate to be processed 12.

Next, the micro-wave supplying part 30, which supplies the micro-wave to the radial line slot antenna 20, includes: waveguides 31 connected to the coaxial waveguides 24 at a connecting part 20A; an oscillating part (magnetron) 33 connected to the waveguides 31 via an isolator 34; and an electric power supplying source 32 that supplies electric power to the oscillating part 33 via a wiring part 37.

When the micro-wave is supplied to the radial line slot antenna 20, the electric power is supplied from the electric power supplying source 32 to the oscillating part 33, the micro-wave is formed in the oscillating part 33, and the micro-wave is introduced from the waveguides 31 to the radial line slot antenna 20 via the isolator 34. The isolator 34 has a function to protect the oscillating part and the electric power supplying source from reflection wave of the micro-wave.

In the present embodiment, a state of the micro-wave introduced from the radial line slot antenna 20 into the processing container 11 is measured (captured), and the state of the micro-wave is fed back to the micro-wave supplying part 30. For that purpose, electrical-field measuring units 25 and 26 that measure electric field strength of the micro-wave are mounted at the radial line slot antenna 20.

Wiring parts 25a and 26a are respectively connected to the electrical-field measuring units 25 and 26. The values of the electrical field strength measured by the electric-field measuring units 25 and 26 are adapted to be fed back to the electric power supplying source 32.

The electric power supplying source 32 has a controlling unit 32a therein. The controlling unit 32a controls electric power outputted from the electric power supplying source 32 in such a manner that the values of the electric field strength become appropriate for the substrate process. For example, in the processing part 10, the electric power outputted from the electric power supplying source 32 is controlled based on conditions for each substrate process in such a manner that the electric field strength of the micro-wave becomes appropriate in order to conduct a surface oxidation, a surface nitridation, a surface oxynitridation, a film forming, an etching, or the like.

The control of the electric power of the electric power supplying source may be conducted by a controlling unit 50A that controls the plasma processing apparatus 50. For example, the measured values of the electrical field strength measured by the electric-field measuring units 25 and 26 may be sent to the controlling unit 50A, and the controlling unit 50A may control the introduced electric power in such a manner that the values of the electric field strength become appropriate for the substrate process. Herein, electric wires for the controlling unit 50A are omitted in the drawings.

In addition, setting of the electric power of the electric power supplying source 32, control of the electric power introduced from the electric power supplying source 32, control of the micro-wave supplying part 30 such as control and monitoring of the oscillating part 33 and the isolator 34, control of an introduction way (not shown) for introducing the plasma gas into the processing container 10, control of the substrate processing part 10 such as gas-discharging of the processing container 11 necessary for the substrate process, and so on are carried out by the controlling unit 50A.

As described above, in the present embodiment, it is possible to measure (capture) the electric field strength of the micro-wave introduced from the radial line slot antenna 20, which has a direct relationship with a processing state of the substrate process such as a surface oxidation, a surface nitridation, a surface oxynitridation, a film forming or an etching. Thus, it becomes possible to accurately measure the state of the substrate process.

In addition, the electric power introduced from the electric power supplying source 32 is controlled in such a manner that the electric field strength of the micro-wave introduced from the radial lie slot antenna 20, which has a direct relationship with the processing state of the substrate, becomes an appropriate value. Thus, it is possible to conduct a process to the substrate stably.

For example, conventionally, the state of the micro-wave in the waveguides 31 has been measured, and the electric power introduced from the electric power supplying source has been determined based on that measurement, and the impedance in the waveguides has been adjusted. That is, on the side of the micro-wave introducing part, the measurement and the control based on that measurement have been conducted. Thus, the state of the micro-wave actually introduced from the radial line slot antenna into the processing container may not be stable, so that the state of the substrate process may not be stable, and/or reproducibility of the substrate process may be inferior.

On the other hand, according to the present embodiment, the electric field strength of the micro-wave introduced from the radial line slot antenna into the processing container is measured, and the electric power introduced from the electric power supplying source is controlled in such a manner that the value(s) of the electric field strength becomes a value necessary for conditions of a substrate process such as a surface oxidation, a surface nitridation, a surface oxynitridation, a film forming or an etching. Thus, the state of the micro-wave actually introduced into the processing container becomes stable, so that the substrate process in the plasma processing apparatus is made stable, and reproducibility of the substrate process is improved.

In addition, for example, if the plasma processing apparatus 50 is mass-produced, since the electric power supplying source 32 and the oscillating part 33 are large, installation location thereof may be different among the plurality of plasma processing apparatuses. Then, the shape and the length of the waveguides 31 may be not the same between the apparatuses.

In that case, if the state of the micro-wave in the waveguides 31 is measured, the electric power introduced from the electric power supplying source is determined based on that measurement, and the impedance in the waveguides is adjusted, that is, if measurement and control based on the measurement are conducted on the side of the micro-wave introducing part, since the shape and the length of the waveguides are different, the micro-wave introduced from the antenna may be different between the apparatuses, so that dispersion may be generated in the substrate process between the apparatuses.

According to the present embodiment, the electric field strength of the micro-wave introduced from the radial line slot antenna into the processing container is measured, and the electric power introduced from the electric power supplying source is controlled based on that measurement. Thus, even if the supplying part of the micro-wave is modified or even if there is some difference between the apparatuses, the electric field strength of the micro-wave actually introduced into the processing container may be made substantially uniform. Thus, the difference between the apparatuses in the state of the substrate process may be made less, so that substantially the same process may be carried out by the plurality of apparatuses.

In addition, in a case of a plasma processing apparatus having a plurality of processing containers, such as a cluster-tool type of plasma processing apparatus, it may be difficult to make uniform the shapes of waveguides used for the plurality of processing containers. Then, if the present embodiment is adopted, even if the shapes of the waveguides are different, since the electric field strength of the micro-wave actually introduced from the antenna is controlled, the difference between the plurality of processing containers in the state of the substrate process may be made less, so that substantially the same substrate process may be carried out stably by the plurality of processing containers.

Next, the electric-field measuring units 25 and 26 are explained with reference to the drawings.

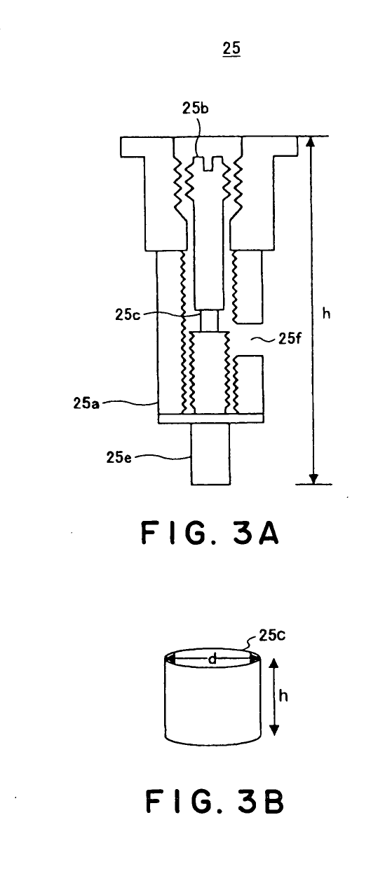

FIG. 3A is an enlarged sectional view of the electric-field measuring unit 25 mounted on the plasma processing apparatus 50. Herein, the electric-field measuring unit 26 has the same structure as the electric-field measuring unit 25, so that explanation thereof is omitted.

With reference to FIG. 3A, the electric-field measuring unit 25 consists of an electric-field measuring probe having the total length h of about 20 mm, for example. A threaded portion 25b and a measurement terminal 25e, consisting of an electric conductor, are inserted into an outside container 25a having a substantially cylindrical shape and made of an electric insulator such as a ceramic. The threaded portion 25b and the measurement terminal 25e are electrically connected by a semiconductor material 25c consisting of a diode. By means of half-wave rectification of the diode, an electric field strength (electric voltage) measured by the measurement terminal 25e is adapted to be derived.

FIG. 3B shows the semiconductor material 25c consisting of the diode, which is sandwiched between the threaded portion 25b and the measurement terminal 25e. The semiconductor material 25c has a shape in which a diameter d is 1 mm and a height h is 3 mm.

An insulation material is inserted from an opening 25f to fill a gap in the electric-field measuring unit 25, in order to stabilize characteristics of the electric-field measuring unit 25.

Next, an installing way of the electric-field measuring units 25 and 26 is explained.

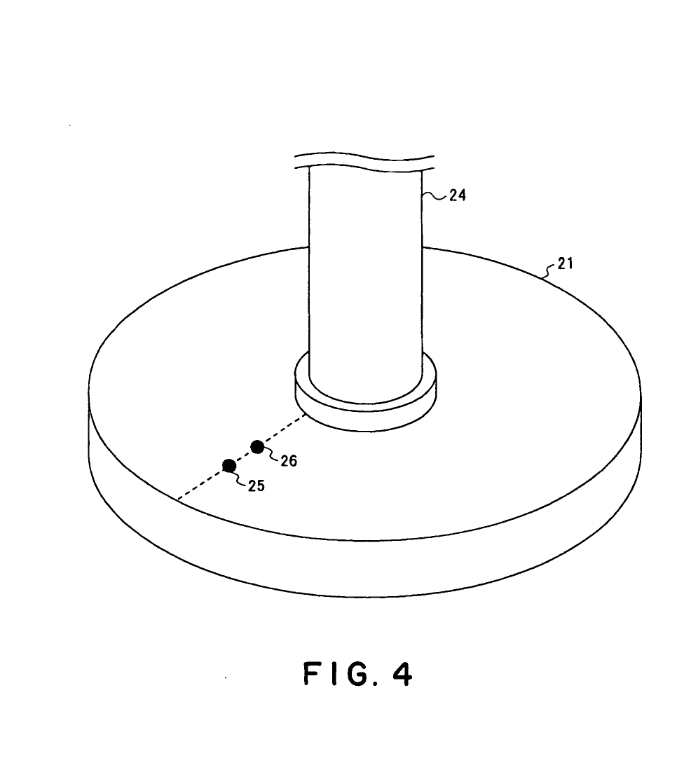

FIG. 4 is a perspective view of the radial line slot antenna 20 used for the plasma processing apparatus 50. In the drawing, the portions that have been explained above are accompanied with the same numerical signs, and explanation thereof is omitted.

With reference to FIG. 4, the electric-field measuring units 25 and 26 are inserted into openings provided in the antenna main body 21, for example. In the case, the electric-field measuring units 25 and 26 are preferably arranged in a linear direction correspondingly to a radial direction of the disk-like antenna main body 21.

Next, the installation of the electric-field measuring units 25 and 26 is explained in detail, and an electric field of the micro-wave to be measured is also explained.

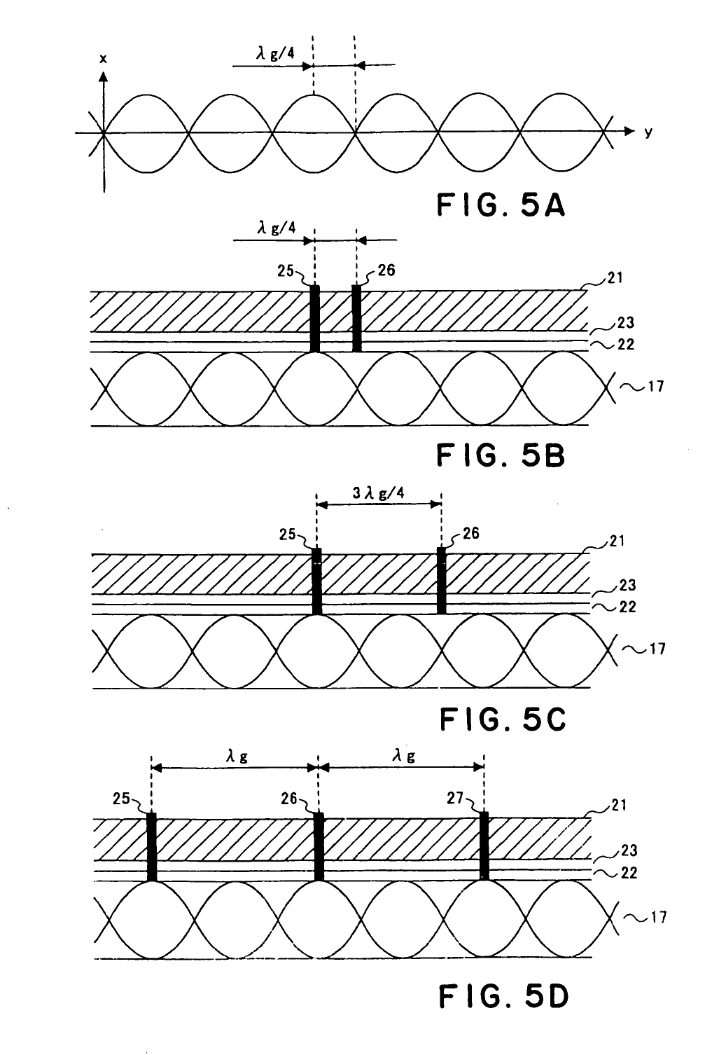

FIG. 5A schematically shows a standing wave formed by a micro-wave introduced into the processing container 11 of the plasma processing apparatus 50. FIGS. 5B to 5D are schematic sectional views showing examples of the electric field measuring units mounted on the radial line slot antenna. In these drawings, the portions that have been explained above are accompanied with the same numerical signs, and explanation thereof is omitted.

At first, with reference to FIG. 5A, FIG. 5A schematically shows a standing wave formed by the micro-wave. In the plasma processing apparatus 50, the micro-wave is supplied into the processing container 11 by the radial line slot antenna 20. In that case, as shown in FIG. 5A, a standing wave of the micro-wave is formed in the micro-wave transmission window 17, from which the micro-wave is supplied into the processing container 11.

Thus, as a way for measuring the electric field strength of the micro-wave supplied from the radial line slot antenna 20 into the processing container 11, there is a way of measuring an electric voltage of a standing wave formed in the micro-wave transmission window 17.

For example, the wavelength λ_{g} of the standing wave formed in the micro-wave transmission window 17 is obtained as follows.

At first, when the propagation velocity V of the micro-wave in the air is 3×10¹⁰ cm/s, and the frequency of the micro-wave is f (=2.45 GHz), the wavelength λ₀ of the micro-wave in the air is expressed as follows.

$${λ}_{o} = \frac{V}{f} = 12.24 cm \qquad < expression 1 >$$

In addition, when dielectric constant ∈ of the ceramic used for the micro-wave transmission window 17 is 9.7, and magnetic permeability p thereof is 1, the wavelength λ_{g} of the micro-wave in the micro-wave transmission window 17 is expressed as follows.

$${λ}_{g} = \frac{{λ}_{o}}{\sqrt{ɛ \cdot μ}} = 3.9 cm \qquad < expression 2 >$$

Then, as shown in FIG. 5B, the electric-field measuring units 25 and 26 are installed on the radial line slot antenna 20, in order to measure the electric voltage of the standing wave formed in the micro-wave transmission window 17.

FIG. 5B is a part of a sectional view of the radial line slot antenna and the micro-wave transmission window 17. FIG. 5B schematically shows the standing wave formed in the micro-wave transmission window 17. In that drawing, the portions that have been explained above are accompanied with the same numerical signs, and explanation thereof is omitted. (Hereinafter, this is the same for FIGS. 5C and 5D.)

With reference to FIG. 5B, for example, if the measuring unit 25 is installed at a loop of the standing wave (a portion whose electric voltage is the highest) and the measuring unit 26 is installed at a node of the standing wave (a portion whose electric voltage is the lowest), it becomes possible to measure the size of the standing wave. For example, in the case, the measuring units 25 and 26 are inserted into openings formed in the antenna main body 21, the slow-wave plate 23 and the slot plate 22, and the measurement terminal 25e shown in FIG. 5 is set to come in contact with the surface of the micro-wave transmission window 17. Then, the electric voltage of the surface of the micro-wave transmission window 17 is measured by the measurement terminal 25e. Herein, the distance between the measuring unit 25 and the measuring unit 26 is λ_{g}/4, for example.

In addition, the installing way shown in FIG. 5B may be modified to that shown in FIG. 5C.

With reference to FIG. 5C, in this case, the distance between the measuring unit 25 and the measuring unit 26 is 3λ_{g}/4. Similarly, the distance between the measuring unit 25 and the measuring unit 26 may be made λ_{g}/4 multiplied by an odd number.

In addition, the installing way shown in FIG. 5B may be modified to that shown in FIG. 5D.

With reference to FIG. 5D, in this case, the measurement of the electric voltage at a node of the standing wave is omitted, and the electric voltage at a loop of the standing wave is measured. This is because the electric voltage at a node of the standing wave is considered to be substantially zero and the measuring unit at a node of the standing wave is omitted. Thus, it is possible to reduce the number of the measuring units, for example to one as a minimum. In this case, the structure is simplified, so that cost of the plasma processing apparatus is reduced. On the other hand, as shown in FIGS. 5B and 5C, if a plurality of electric-field measuring units are used to measure the electric voltages at a loop portion of the standing wave and at a node portion of the standing wave, it is possible to detect a change in the state of the standing wave for example when the substrate processing conditions are greatly changed or when an abnormal situation occurs in the apparatus.

In addition, in the example shown in the drawing, the distance between the measuring unit 25 and the measuring unit 26 is λ_{g}, and another measuring unit 27 is installed away from the measuring unit 26 by λ_{g}.

Thus, for example, it becomes possible to confirm uniformity of the micro-wave within the surface of the micro-wave transmission window 17. In addition, it becomes possible to detect a great change in the state of the standing wave within the surface of the micro-wave transmission window 17 when the substrate processing conditions are greatly changed or when an abnormal situation occurs in the apparatus. In the case, the installation distance between the plurality of measuring units may be λ_{g}/4 multiplied by an even number.

As described above, in the plasma processing apparatus, it is effective to provide a measuring unit that measures an electric field strength of a micro-wave on the micro-wave supplying side, for example on the micro-wave supplying antenna, during a substrate-processing step wherein a large number of substrates is processed, so as to detect an abnormal situation in the substrate process or to confirm history of the substrate process. For example, when the large number of substrates is processed, it becomes easier to check the history of the substrate process by converting into digital data and recording the measurement result of the electric-field measuring units by means of the controlling unit 50A, for example. This is useful for detecting breakdown of the apparatus or occurrence of any abnormal situation in the micro-wave introduction way and hence for managing the manufacturing step of conducting a large number of substrate processes.

Herein, if it is difficult to generate a standing wave at the radial line slot antenna 20, a matching unit may be installed at waveguides 31 between the radial line slot antenna 20 and the isolator 34.

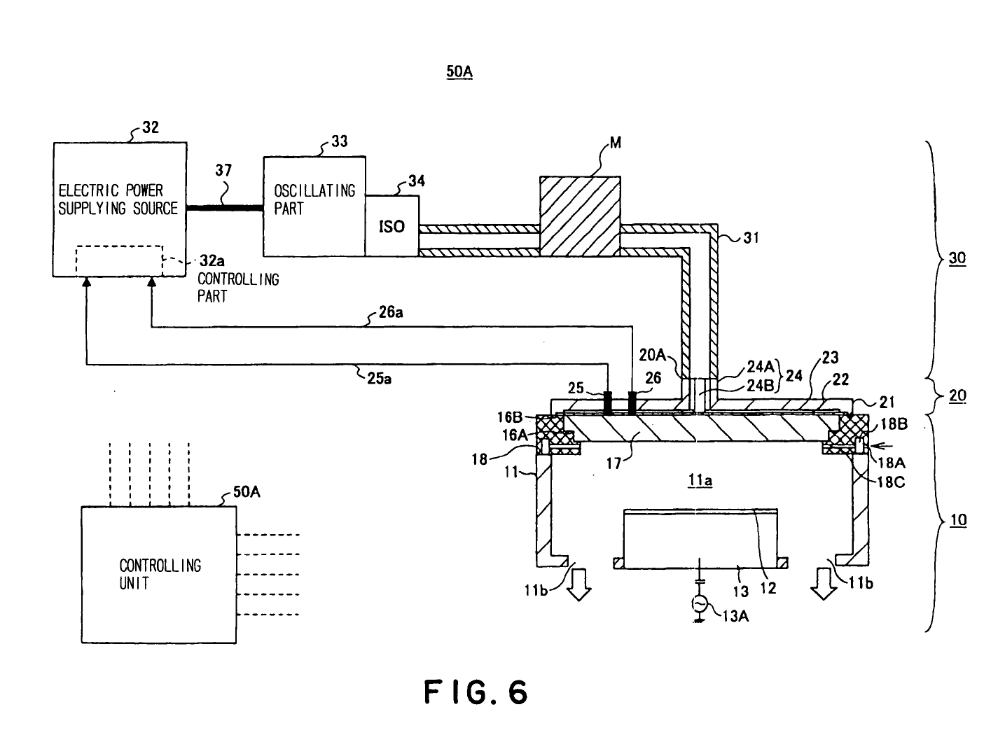

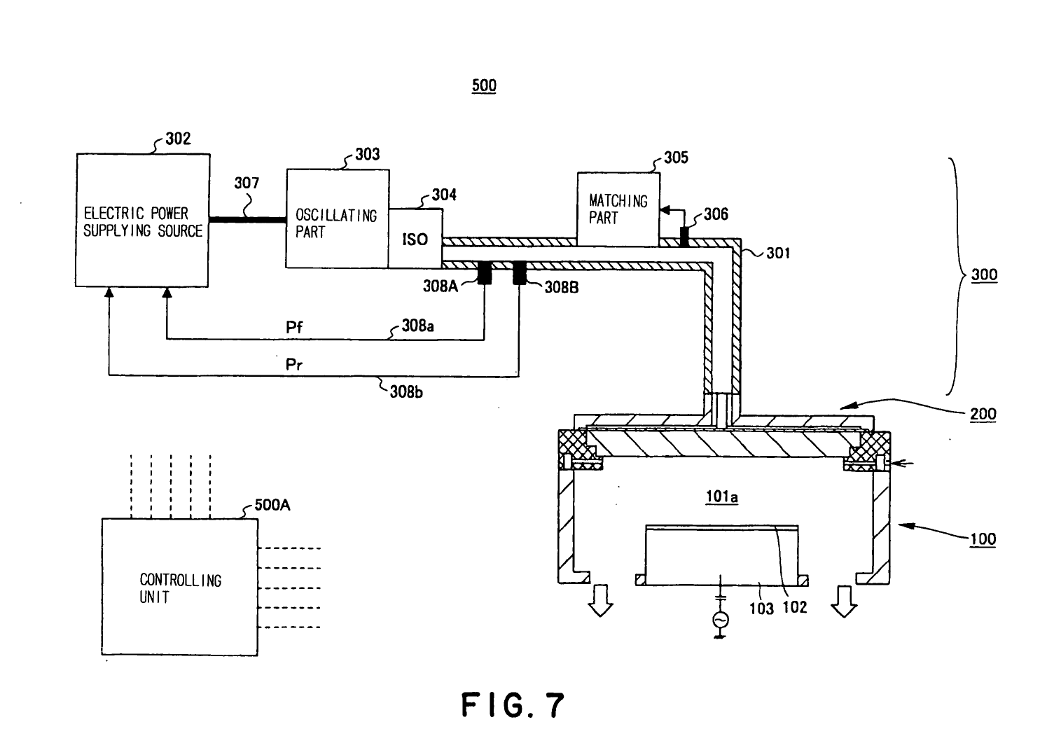

FIG. 6 shows an example of the plasma processing apparatus 50A having the matching unit. In that drawing, the portions that have been explained above are accompanied with the same numerical signs, and explanation thereof is omitted. With reference to FIG. 6, in the plasma processing apparatus shown in the drawing, the matching unit M is installed at the waveguides 31 between the radial line slot antenna 20 and the isolator 34.

Thus, it becomes possible to form a standing wave of the micro-wave by means of the matching unit M. In addition, it is also possible to form a standing wave of the micro-wave by combination of the matching unit M and the radial line slot antenna 20.

Although the preferable embodiments have been explained, the present invention is not limited thereto, but may be variously changed or modified within scopes of attached claims.

According to the present invention, a plasma processing apparatus that makes it possible to conduct a stable substrate process is provided, by stabilizing a state of a micro-wave used for the substrate process.

1. A plasma processing apparatus comprising:
a processing container having a holding stage that holds a substrate to be processed;
a micro-wave transmission window provided on or above the processing container, opposite to the substrate to be processed placed on the holding stage;
a micro-wave antenna provided on or above the micro-wave transmission window, opposite to the micro-wave transmission window, for supplying a micro-wave into the processing container;
a micro-wave electric power supplying source connected to the micro-wave antenna;
an electric-field measuring unit that measures electric field strength of the micro-wave supplied by the micro-wave antenna;
a controlling unit that controls the micro-wave electric power supplying source based on the electric field strength measured by the electric-field measuring unit, and
wherein the electric-field measuring unit is arranged at a loop of a standing wave formed in the micro-wave transmission window.

2. A plasma processing apparatus according to claim 1, wherein
the micro-wave antenna is fed via coaxial waveguides, and
the micro-wave antenna has: an antenna main body having an opening; a micro-wave radiation surface provided on or above the antenna main body so as to cover the opening, the micro-wave radiation surface having a plurality of slots; and a dielectric plate provided between the antenna main body and the micro-wave radiation surface.

3. A plasma processing apparatus according to claim 1, wherein
the micro-wave antenna is a radial line slot antenna.

4. A plasma processing apparatus according to claim 1, wherein
the electric-field measuring unit includes an electric-field measuring probe.

5. A plasma processing apparatus according to claim 4, wherein
the electric-field measuring probe has a structure in which a threaded portion and a measurement terminal that consist of an electric conductor are inserted into an outside container having a substantially cylindrical shape and made of an electric insulator, and in which the threaded portion and the measurement terminal are electrically connected by a semiconductor material.

6. A plasma processing apparatus according to claim 5, wherein
the semiconductor material is a diode.

7. A plasma processing apparatus according to claim 4, wherein
the electric-field measuring probe has an opening for infilling of an insulation material.

8. A plasma processing apparatus according to claim 1, wherein
the electric-field measuring unit is adapted to measure an electric voltage on or above a surface of the micro-wave transmission window.

9. A plasma processing apparatus according to claim 1, wherein
the electric-field measuring unit is attached on or above the micro-wave antenna.

10. A plasma processing apparatus according to claim 1, wherein
a plurality of electric-field measuring units is provided.

11. A plasma processing apparatus according to claim 10, wherein
the plurality of electric-field measuring units is arranged in a linear direction corresponding to a radial direction of a disk-like antenna main body.

12. A plasma processing apparatus according to claim 10, wherein
one of the plurality of electric-field measuring units is arranged at a node of the standing wave formed in the micro-wave transmission window.

13. A plasma processing apparatus according to claim 10, wherein
when a wavelength of the standing wave formed in the microwave transmission window is expressed as λ, a distance between the plurality of electric-field measuring units is λ/4 multiplied by an odd number.

14. A plasma processing apparatus according to claim 10, wherein
when a wavelength of the standing wave formed in the microwave transmission window is expressed as λ, a distance between the plurality of electric-field measuring units is λ/4 multiplied by an even number.

15. A plasma processing apparatus according to claim 1, further comprising
a controlling unit that converts into digital data and records measurement results by the electric-field measuring unit.
